(19) United States
(12) Patent Application Publication
(10) Pub. No.: US 2025/0210310 A1
(43) Pub. Date: Jun. 26, 2025

(54) MANUFACTURING METHOD, PROCESS MODULE MATCHING METHOD, AND SUBSTRATE PROCESSING APPARATUS

(71) Applicant: SEMES CO., LTD., Cheonan-si (KR)

(72) Inventor: Sang Moon YOO, Hwaseong-si (KR)

(73) Assignee: SEMES CO., LTD., Cheonan-si (KR)

(21) Appl. No.: 18/988,265

(22) Filed: Dec. 19, 2024

(30) Foreign Application Priority Data
Dec. 20, 2023 (KR) 10-2023-0186977

(51) Int. Cl. H01J 37/32; G05B 13/02

(52) U.S. Cl. CPC H01J 37/32183; G05B 13/021; H01J 37/32899; H01J 2237/24564; H01J 2237/334

(57) ABSTRACT

Disclosed is a manufacturing method including: a device setup operation of matching resonance points of a first process module and a second process module different from the first process module with each other; a first substrate processing operation of processing a substrate in the first process module and/or the second process module; and a resonant frequency control operation of adjusting the resonance points of the first process module and the second process module that change while performing the first substrate processing operation to initial resonance points, in which the resonant frequency control operation includes controlling at least one of a variable element of a first resonance control circuit of the first process module and a variable element of a second resonance control circuit of the second process module to adjust the resonance points of the first process module and the second process module to the initial resonance points.

### CROSS-REFERENCE TO RELATED APPLICATIONS

This application claims priority to and the benefit of Korean Patent Application No. 10-2023-0186977 filed in the Korean Intellectual Property Office on Dec. 20, 2023, the entire contents of which are incorporated herein by reference.

### TECHNICAL FIELD

The present invention relates to a manufacturing method, a process module matching method, and a substrate processing apparatus, and more particularly to a manufacturing method of manufacturing a semiconductor device, a method of matching process modules which processes a substrate by using plasma for manufacturing a semiconductor device, and a substrate processing apparatus.

### BACKGROUND ART

To manufacture semiconductor devices, various processes, such as photography, deposition, etching, and ion implantation, are performed on substrates, such as wafers. Among them, the deposition process and the etching process use plasma to process the substrate. In the deposition process, plasma is used to form a film on the substrate. In the etching process, plasma is used to remove the film formed on the substrate.

On the other hand, it takes a certain amount of time to process a substrate using plasma. Therefore, one substrate processing apparatus (semiconductor manufacturing facility) includes a plurality of process modules. Each process module processes a substrate. The substrate processing apparatus includes a plurality of process modules, so that the quantity of substrates that the substrate processing apparatus is capable of processing per unit time increases.

Generally, the process modules provided in a single substrate processing apparatus may perform the same kind of process. That is, the process modules may be operated with the same process recipe. Preferably, the degree of processing of substrates processed by the process modules operated with the same process recipe is the same. For example, the etch rates for substrates processed in the process modules that perform the same etch process with the same process recipe are preferably the same.

However, the degree of processing of the substrates processed in each of the process modules may vary. Due to machining errors in the configurations of the process modules, the impedance across the process module from the RF power source may vary. Also, because the numbers of times of driving of the process modules are different from each other, the degree of deformation of the configurations of the process modules may be differently.

Therefore, in order to ensure the same degree of substrate processing between the process modules, Tool To Tool Matching (TTTM) is required.

### SUMMARY OF THE INVENTION

The present invention has been made in an effort to provide a manufacturing method, a process module matching method, and a substrate processing apparatus that may effectively process a substrate.

The present invention has also been made in an effort to provide a manufacturing method, a process module matching method, and a substrate processing apparatus that enables the degree of processing between substrates to be substantially the same.

The present invention has also been made in an effort to provide a manufacturing method, a process module matching method, and a substrate processing apparatus that are capable of adjusting a resonance point of a process module.

The present invention has also been made in an effort to provide a manufacturing method, a process module matching method, and a substrate processing apparatus that are capable of matching resonance points between process modules.

The problem to be solved by the present invention is not limited to the above-mentioned problems, and the problems not mentioned will be clearly understood by those skilled in the art from the descriptions below.

An exemplary embodiment of the present invention provides a manufacturing method including: a device setup operation of matching resonance points of a first process module and a second process module different from the first process module with each other; a first substrate processing operation of processing a substrate in the first process module and/or the second process module; and a resonant frequency control operation of adjusting the resonance points of the first process module and the second process module that change while performing the first substrate processing operation to initial resonance points, in which the resonant frequency control operation includes controlling at least one of a variable element of a first resonance control circuit of the first process module and a variable element of a second resonance control circuit of the second process module to adjust the resonance points of the first process module and the second process module to the initial resonance points.

According to the exemplary embodiment, the first process module may include: a first chamber; a first power source that is an RF power source for generating plasma or regulating a flow of plasma in the first chamber; a first cable coupled to an RF signal applied by the first power source; and a first impedance controller coupled to the first cable, and the second process module may include: a second chamber; a second power source that is an RF power source for generating plasma or regulating a flow of plasma in the second chamber; a second cable coupled to an RF signal applied by the second power source; and a second impedance controller connected with the second cable.

According to the exemplary embodiment, the device setup operation may include adjusting a length of at least one of the first cable and the second cable.

According to the exemplary embodiment, the device setup operation may include controlling at least one of variable elements of the first resonance control circuit and the second resonance control circuit to match the resonance points of the first process module and the second process module with each other.

According to the exemplary embodiment, the manufacturing method may further include a second substrate processing operation, performed after the resonant frequency control operation, in which the first process module and/or the second process module processes the substrate.

According to the exemplary embodiment, the resonant frequency control operation may be performed when a set number or more of substrates have been processed in the first substrate processing operation.

According to the exemplary embodiment, the resonant frequency control operation may be performed when a set period of time has elapsed since the first substrate processing operation has been performed.

Another exemplary embodiment of the present invention provides a process module matching method of matching resonance points of a plurality of process modules, in which the plurality of process modules each includes a chamber, a controller, and a cable connecting the controller and the chamber, and the resonance points of the plurality of process modules are matched by differentiating lengths of the cables of the plurality of process modules.

According to the exemplary embodiment, each of the cables may be provided with a resonance control circuit including at least one variable element, and the plurality of process modules may regulate the variable elements of the resonance control circuits after processing a set number of substrates.

According to the exemplary embodiment, the resonance points of the process modules may be matched by adjusting the variable elements.

According to the exemplary embodiment, the resonance points of the process modules may be matched to the initial resonance points by adjusting the variable elements.

Still another exemplary embodiment of the present invention provides an apparatus for processing a substrate, the apparatus including: a first process module for processing a substrate by using plasma, in which the first process module includes: a first chamber providing an interior space in which a substrate is processed by using plasma; a first edge impedance controller included in the first process module, and RF-coupled to a first ring electrode positioned a lower side of an edge region of the substrate processed in the first process module, to control plasma flow in the edge region of the substrate; a first cable having one end and the other end connected to the first chamber and the first edge impedance controller, respectively; and a first resonance control circuit provided in the first cable, for controlling a resonance point that is changed by deformation of the first cable.

According to the exemplary embodiment, the first resonance control circuit may include at least one variable element.

According to the exemplary embodiment, the apparatus may further include a controller configured to control the first resonance control circuit, in which the controller controls at least one of the variable elements of the first resonance control circuit to adjust a resonance point of the first process module to an initial resonance point after the first process module processes a set number of substrates.

According to the exemplary embodiment, the apparatus may further include a second process module for processing a substrate by using plasma, in which the second process modules may include: a second chamber providing an interior space in which the substrate is processed by using plasma; a second edge impedance controller included in the second process module, and RF-coupled to a second ring electrode positioned at a lower side of an edge region of the substrate processed in the second process module, to control plasma flow in the edge region of the substrate; a second cable having one end and the other end connected to the second chamber and the second edge impedance controller, respectively; and a second resonance control circuit provided in the second cable, for controlling a resonance point that is changed by deformation of the second cable.

According to the exemplary embodiment, the apparatus may further include a controller configured to control the first resonance control circuit and the second resonance control circuit, in which the controller may control at least one of the variable elements included in the first resonance control circuit and the second resonance control circuit to match a resonance point of the first process module with a resonance point of the second process module.

According to the exemplary embodiment, the first cable and the second cable may have different lengths.

According to the exemplary embodiment, the apparatus may further include a controller configured to control the first resonance control circuit and the second resonance control circuit, in which the controller may adjust the resonance point of the first process module and the resonance point of the second process module to the initial resonance points by controlling at least one of the variable elements included in the first resonance control circuit and the second resonance control circuit after processing a set number of substrates in the first process module and the second process module, or after a set period of time has elapsed after a set number of substrates is processed in the first process module and the second process module.

According to the exemplary embodiment, the first resonance control circuit may include: a plurality of variable capacitors connected in parallel; and an inductor connected in series with the plurality of variable capacitors.

According to the exemplary embodiment, the first resonance control circuit may include a sensor positioned between the inductor and the first edge impedance controller, and the sensor may be a sensor capable of measuring current and/or voltage.

According to the exemplary embodiment of the present invention, the substrates may be treated effectively.

Further, according to the exemplary embodiment of the invention, the degree of processing between substrates may be substantially the same.

Further, according to the exemplary embodiment of the invention, the resonance point of the process module may be adjusted.

Further, according to the exemplary embodiment of the invention, the resonance points between process modules may be matched.

The effect of the present invention is not limited to the foregoing effects, and those skilled in the art may clearly understand non-mentioned effects from the present specification and the accompanying drawings.

### BRIEF DESCRIPTION OF THE DRAWINGS

FIG. 1 is a top plan view for illustrating a substrate processing apparatus according to an exemplary embodiment of the present invention.

FIG. 2 is a diagram for illustrating process modules provided by the substrate processing apparatus of FIG. 1.

FIG. 3 is a diagram for illustrating a matching method of process modules according to an exemplary embodiment of the present invention.

FIG. 4 is a graph for illustrating the variation of a resonance point when a cable connecting an edge impedance controller and a chamber changes.

FIG. 5 is a flow chart for illustrating a substrate processing method according to an exemplary embodiment of the present invention.

FIG. 6 is a diagram for illustrating a method of matching process modules according to another exemplary embodiment of the present invention.

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

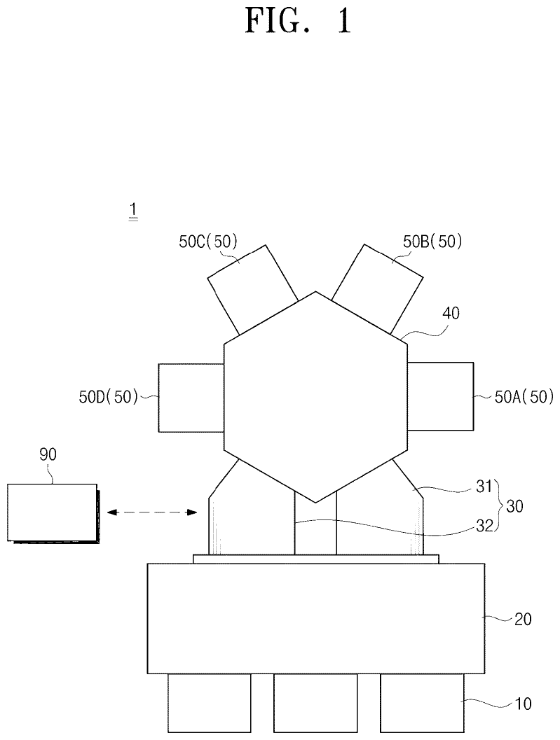

FIG. 1 is a top plan view for illustrating a substrate processing apparatus according to an exemplary embodiment of the present invention.

Referring to FIG. 1, a substrate processing apparatus 1 according to an exemplary embodiment of the present invention may process a substrate W, such as a wafer. The substrate processing apparatus 1 may treat the substrate W by using plasma. The substrate processing apparatus 1 may perform an etching process to remove a film on the substrate W by using plasma, or a deposition process to form a film on the substrate W by using plasma. In the following, the present invention has been described based on the case where the substrate processing apparatus 1 performs the etching process to remove a film on the substrate W, as an example.

In addition, the substrate processing apparatus 1 may perform a process for manufacturing a semiconductor device. The substrate processing apparatus 1 may be a semiconductor manufacturing facility that performs some of the various processes required to manufacture a semiconductor device. A substrate processing method, described below, may be a manufacturing method of manufacturing a semiconductor device.

The substrate processing apparatus 1 according to the exemplary embodiment of the present invention may include a load port 10, an interface module 20, a load lock chamber 30, a transfer module 40, and a process module 50.

In the load port 10, a container in which a plurality of substrates W is accommodated may be placed. The container may be a container that may be referred to as a FOUP, cassette, POD, or the like. The containers may be transferred to the load port 10 by an Overhead Transport Apparatus (OHT), an Auto Vehicle Robot (AVR), or the like.

The unprocessed substrates W accommodated in the containers placed in the load port 10 may be transferred to the load lock chamber 30 by a transfer robot provided in the interface module 20. Additionally, the processed substrates W transferred to the load lock chamber 30 may be transferred to the container placed in the load port 10 by the transfer robot provided in the interface module 20. The pressure in the interior space of the interface module 20 may be maintained at normal pressure.

The load lock chamber 30 may be positioned between the interface module 20 and the transfer module 40. The load lock chamber 30 may include a first load lock chamber 31 and a second load lock chamber 32. The first load lock chamber 31 may provide a pathway for the unprocessed substrate W to be transferred to the process module 50, and the second load lock chamber 32 may provide a pathway for the substrate W processed in the process module 50 to be transferred to the container placed in the load port 10.

The pressure in the load lock chamber 30 may be switched between normal pressure and vacuum pressure. For example, when the transfer robot of the interface module 20 loads the substrate W unloaded from the container into the first load lock chamber 31, the pressure in the first load lock chamber 31 may be switched from normal pressure to vacuum pressure. Further, when the substrate W processed in the process module 50 is loaded into the second load lock chamber 32, the pressure in the second load lock chamber 32 may be switched from vacuum pressure to normal pressure. In other words, the load lock chamber 30 may function as a pressure switching gate by being disposed between the interface module 20, which is maintained at normal pressure, and the transfer module 40, which is maintained at vacuum pressure, as described later.

The transfer module 40 may be provided with a transfer robot. The interior space of the transfer module 40 may be maintained at vacuum pressure. The vacuum pressure in the interior space of the transfer module 40 does not mean a perfect vacuum pressure (ideal vacuum pressure), but may mean a vacuum pressure equal to or greater than the vacuum pressure maintained for processing the substrate W in the process module 50. The transfer robot provided in the transfer module 40 may be configured to transfer the substrate W between the load lock chamber 30 and the transfer module 50.

The process module 50 may process the substrate W. The process module 50 may be a module that performs a processing process on the substrate W. The process module 50 may be coupled to the transfer module 40. The process module 50 may have a plurality of process modules. For example, the substrate processing apparatus 1 may include a first process module 50A, a second process module 50B, a third process module 50C, and a fourth process module 50D. The first process module 50A, the second process module 50B, the third process module 50C, and the fourth process module 50D may perform the same process. The first process module 50A, the second process module 50B, the third process module 50C, and the fourth process module 50D may be operated with the same process recipe.

The first process module 50A, the second process module 50B, the third process module 50C, and the fourth process module 50D may have the same structure. The specific structure of the process module 50 will be described later.

The controller 90 may control the substrate processing apparatus 1. The controller 90 may control the substrate processing apparatus 1 to perform a substrate processing method, which is a semiconductor device manufacturing method described later.

The controller 90 may control the configurations of the substrate processing apparatus 1. The controller 90 may include a process controller formed of a microprocessor (computer) that executes the control of the substrate processing apparatus 1, a user interface formed of a keyboard in which an operator performs a command input operation or the like in order to manage the substrate processing apparatus 1, a display for visualizing and displaying an operation situation of the substrate processing apparatus 1, and the like, and a storage unit storing a control program for executing the process executed in the substrate processing apparatus 1 under the control of the process controller or a program, that is, a processing recipe, for executing the process in each component according to various data and processing conditions. Further, the user interface and the storage unit may be connected to the process controller. The processing recipe may be memorized in a storage medium in the storage unit, and the storage medium may be a hard disk, and may also be a portable disk, such as a CD-ROM or a DVD, or a semiconductor memory, such as a flash memory.

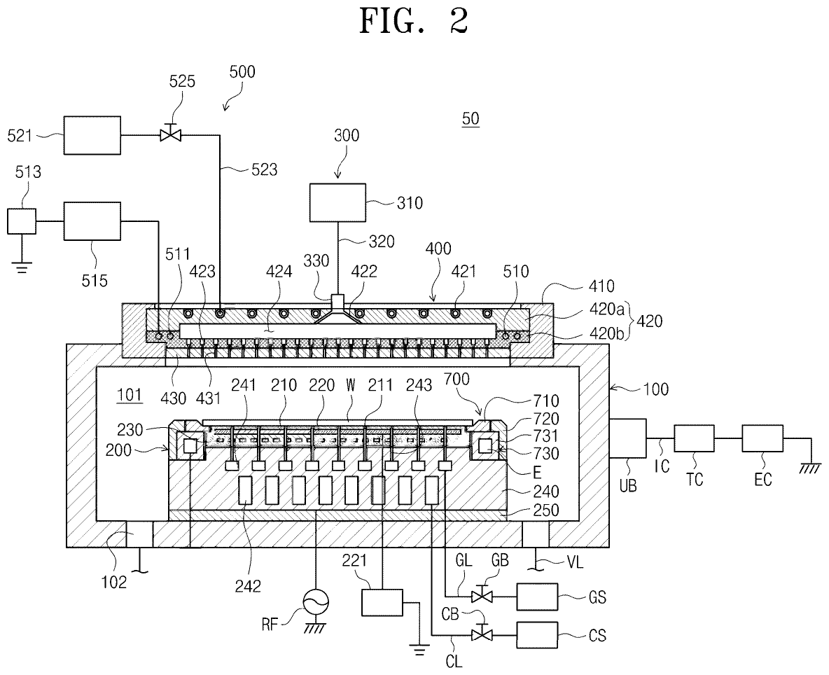

FIG. 2 is a diagram for illustrating process modules provided by the substrate processing apparatus of FIG. 1.

Referring to FIG. 2, the process module 50 may include a chamber 100, a support unit 200 (one example of a lower electrode unit), a gas supply unit 300, an upper electrode unit 400, a temperature control unit 500, a power source RF, a ring unit 700, a utility box UB, a cable IC, a resonance control circuit TC, and an edge impedance controller EC.

The chamber 100 may have an interior space 101. In the interior space 101, the substrate W may be processed. In the interior space 101, the substrate W may be processed by plasma. The substrate W may be etched by the plasma. The plasma may be delivered to the substrate W and may etch a film formed on the substrate W.

The inner wall of the chamber 100 may be coated with a material having excellent plasma resistance. The chamber 100 may be grounded. The chamber 100 may be formed with an entrance opening (not illustrated) through which the substrate W may be loaded and unloaded. The entrance opening may be selectively opened or closed by a door (not illustrated). While the substrate W is being processed, the interior space 101 may be closed by the entrance opening. Additionally, the interior space 101 may have a vacuum pressure atmosphere while the substrate W is being processed.

An exhaust hole 102 may be formed at the bottom of the chamber 100. Through the exhaust hole 102, the atmosphere of the interior space 101 may be exhausted. The exhaust hole 102 may be connected with an exhaust line VL that provides pressure reduction to the interior space 101. Process gases, plasma, process by-products, and the like supplied to the interior space 101 may be exhausted to the outside of the substrate processing apparatus 1 through the exhaust hole 102 and the exhaust line VL. Furthermore, the pressure in the interior space 101 may be regulated by the pressure reduction provided by the exhaust line VL. For example, the pressure in the interior space 101 may be regulated by the pressure reduction provided by the gas supply unit 300 and the exhaust line VL described later. When a further reduction in pressure in the interior space 101 is desired, the pressure reduction provided by the exhaust line VL may be increased, or the amount of process gas supplied per unit time by the gas supply unit 300 may be decreased. Conversely, when a higher pressure in the interior space 101 is desired, the pressure reduction provided by the exhaust line VL may be reduced, or the amount of process gas supplied per unit time by the gas supply unit 300 may be increased.

The support unit 200 may support the substrate W. The support unit 200 may support the substrate W in the interior space 101. The support unit 200 may have any one of opposing electrodes forming an electric field in the interior space 101. Further, the support unit 200 may be an electrostatic chuck (ESC) that may adsorptively hold the substrate W by using electrostatic force.

The support unit 200 may include a dielectric plate 210, a capacitive electrode 220, a heater 230, a lower electrode 240, and an insulating plate 250.

The dielectric plate 210 may be provided on the top of the support unit 200. The dielectric plate 210 may be provided with an insulating material. For example, the dielectric plate 210 may be provided from a material including ceramic, or quartz. The dielectric plate 210 may have a seating surface that supports the substrate W. The dielectric plate 210 may have a seating surface that is smaller in area than the bottom surface of the substrate W when viewed from above. The bottom surface of the edge region of the substrate W placed on the dielectric plate 210 may face the top surface of the edge ring 710 described later.

A first supply flow path 211 is formed in the dielectric plate 210. The first supply flow path 211 may be formed by extending from a top to a lower surface of the dielectric plate 210. The first supply flow paths 211 are formed in a plurality spaced apart from each other and may be provided as passages through which heat transfer medium is supplied to the underside of the substrate W. For example, the first supply flow path 211 may be in fluid communication with a first circulation flow path 241 and a second supply flow path 243 described later.

In addition, the dielectric plate 210 may have separate electrodes (not illustrated) embedded in the dielectric plate 210 for adsorbing the substrate W onto the dielectric plate 210. A direct current may be applied to the electrode. By the applied current, electrostatic force acts between the electrode and the substrate, and the substrate W may be adsorbed to the dielectric plate 210 by the electrostatic force.

The electrostatic electrode 220 may generate electrostatic forces to chuck the substrate W. The electrostatic electrode 220 may be provided within the dielectric plate 210. The electrostatic electrode 220 may be embedded within the dielectric plate 210. The electrostatic electrode 220 may be electrically connected to an electrostatic power source 221. The electrostatic power source 221 may selectively chuck the substrate W by applying power to the electrostatic electrode 220.

The heater 230 is electrically connected with an external power supply (not illustrated). The heater 230 generates heat by resisting current applied from the external power supply. The generated heat is transferred to the substrate W through the dielectric plate 210. By the heat generated in the heater 230, the substrate W is maintained at a predetermined temperature. The heater 230 includes a spiral-shaped coil. The heaters 230 may be embedded in the dielectric plate 210 at a constant interval.

At the bottom of the dielectric plate 210, the lower electrode 240 is located. The lower electrode 240 may be an electrode that forms an electric field in the interior space 101. The lower electrode 240 may be any one of opposing electrodes that form an electric field in the interior space 101. The lower electrode 240 may be provided to face the other of the opposing electrodes, the upper electrode 420 described later. The electric field formed in the interior space 101 by the lower electrode 240 may excite the process gas supplied by the gas supply unit 300 to generate plasma. The lower electrode 240 may be provided within the oilfield plate 210.

The top surface of the lower electrode 240 may be stepped such that the center region is positioned higher than the edge region. The center region of the top surface of the lower electrode 240 has an area corresponding to the bottom surface of the dielectric plate 210 and is bonded to the bottom surface of the dielectric plate 210. The lower electrode 240 may be formed with a first circulation flow path 241, a second circulation flow path 242, and a second supply flow path 243.

The first circulation flow path 241 is provided as a passage in which a heat transfer medium is circulated. The first circulation flow path 241 may be supplied with heat transfer medium stored in a heat transfer medium storage unit GS via a medium supply line GL. The medium supply line GL may be equipped with a medium supply valve GB. By changing on/off or the opening rate of the medium supply valve GB, the supply of the heat transfer medium to the first circulation flow path 241 or the supply flow rate per unit time of the heat transfer medium supplied to the first circulation flow path 241 may be adjusted. The heat transfer medium may include helium (He) gas.

The first circulation flow path 241 may be formed in a spiral shape inside the lower electrode 240. Otherwise, the first circulation flow paths 241 may be arranged such that the ring-shaped flow paths having different radii have the same center. Each of the first circulation flow paths 241 may communicate with each other. The first circulation flow paths 241 are formed at the same height.

The second circulation flow path 242 is provided as a passage in which a cooling fluid is circulated. The second circulation flow path 242 may be supplied with a cooling fluid stored in a cooling fluid storage unit CS via a fluid supply line CL. The fluid supply line CL may be equipped with a fluid supply valve CB. By changing on/off or the opening rate of the fluid supply valve CB, the supply of the cooling fluid to the second circulation flow path 242 or the supply flow rate per unit time of the cooling fluid supplied to the second circulation flow path 242 may be adjusted. The cooling fluid may be coolant or cooling gas. The cooling fluid supplied to the second circulation flow path 242 may cool the lower electrode 240 to a predetermined temperature. The lower electrode 240 cooled to the predetermined temperature may cause the temperature of the dielectric plate 210 and/or the substrate W to be maintained at the predetermined temperature.

The second circulation flow path 242 may be formed in a spiral shape inside the lower electrode 240. Otherwise, the second circulation flow paths 242 may be arranged such that the ring-shaped flow paths having different radii have the same center. Each of the second circulation flow paths 242 may communicate with each other. The second circulation flow path 242 may have a larger cross-sectional area than that of the first circulation flow path 241. The second circulation flow paths 242 are formed at the same height. The second circulation flow paths 242 may be positioned under the first circulation flow paths 241.

The second supply flow path 243 extends upwardly from the first circulation flow path 241 and is provided to the top surface of the lower electrode 240. The second supply flow paths 243 may be provided in a number corresponding to the number of first supply flow paths 211, and make the first circulation flow path 241 and the first supply flow path 211 be in fluid communication with each other.

The insulating plate 250 is provided under the lower electrode 240. The insulating plate 250 is provided with a size corresponding to the size of the lower electrode 240. The insulating plate 250 is positioned between the lower electrode 240 and the bottom surface of the chamber 100. The insulating plate 250 may be provided of an insulating material and may electrically isolate the lower electrode 240 and the chamber 100.

The gas supply unit 300 supplies the process gas to the chamber 100. The gas supply unit 300 includes a gas storage unit 310, a gas supply line 320, and a gas inflow port 330. The gas supply line 320 connects the gas storage unit 310 and the gas inflow port 330, and supplies the process gas stored in the gas storage unit 310 to the gas inflow port 330. The gas inlet port 330 may be installed in a gas supply hole 422 formed in the upper electrode 420.

The upper electrode unit 400 may have an upper electrode 420 opposite the lower electrode 240. Further, the upper electrode unit 400 may be connected to the gas supply unit 300 described above to provide a portion of a supply path for the process gas supplied by the gas supply unit 300. The upper electrode unit 400 may include a support body 410, an upper electrode 420, and a distribution plate 430.

The support body 410 may be coupled to the chamber 100. The support body 410 may be the body to which the upper electrode 420 and the distribution plate 430 of the upper electrode unit 400 are fastened. The support body 410 may be a medium that allows the upper electrode 420 and the distribution plate 430 to be installed in the chamber 100.

The upper electrode 420 may be an electrode opposite the lower electrode 240. The upper electrode 420 may be provided to face the lower electrode 240. An electric field may be formed in the space between the upper electrode 420 and the lower electrode 240. The formed electric field may excite the process gas supplied to the interior space 101 to generate plasma. The upper electrode 420 may be provided in a disk shape. The upper electrode 410 includes an upper plate 410a and a lower plate 420b. The upper electrode 420 may be grounded. However, the present invention is not limited thereto, and the upper electrode 420 may be connected to an RF power source (not illustrated) to apply an RF voltage.

The bottom surface of the upper plate 412a is stepped so that the center region is higher than the edge region. Gas supply holes 422 are formed in the center region of the upper plate 420a. The gas supply holes 422 are connected with the gas inflow port 330, and supply the process gas to a buffer space 424. A cooling flow path 411 may be formed inside the upper plate 410a. The cooling flow path 421 may be formed in a spiral shape. Otherwise, the cooling flow paths 421 may be disposed so that the ring-shaped flow paths having different radii have the same center. The cooling flow path 421 may be supplied with a cooling fluid by the temperature control unit 500 described later. The supplied cooling fluid may circulate along the cooling flow paths 421 and may cool the upper plate 420a.

The lower plate 420b is positioned on the underside of the upper plate 420a. The lower plate 420b is provided with a size corresponding to the upper plate 420a and is positioned facing the upper plate 420a. A top of the lower plate 410b is stepped so that the center region is lower than the edge region. The top surface of the lower plate 420b and the bottom surface of the upper plate 420a are combined to form a buffer space 424. The buffer space 424 is provided as a space in which the gas supplied through the gas supply holes 422 is temporarily stayed before being supplied into the chamber 100. The gas supply holes 423 are formed in the center region of the lower plate 420b. The plurality of gas supply holes 423 is formed while being spaced apart from each other at a predetermined interval. The gas supply holes 413 are connected with the buffer space 423.

The distribution plate 430 is located on the underside of the lower plate 420b. The distribution plate 430 is provided in a disk shape. Distribution holes 431 are formed in the distribution plate 430. The distribution holes 431 are provided from the top surface to the lower surface of the distribution plate 431. The distribution holes 431 are provided in a number corresponding to the number of gas supply holes 423, and are located corresponding to the positions of the gas supply holes 423. The process gas stayed in the buffer space 424 is uniformly supplied into the chamber 100 through the gas supply holes 423 and the distribution holes 431.

The temperature control unit 500 may regulate the temperature of the upper electrode 420. The temperature control unit 500 may include a heating member 511, a heating power source 513, a filter 515, a cooling fluid supply unit 521, a fluid supply channel 523, and a valve 525.

The heating member 511 may heat the lower plate 420b. The heating member 511 may be a heater. The heating member 511 may be a resistive heater. The heating member 511 may be buried in the lower plate 420b. The heating power source 513 may generate power to heat the heating member 511. The heating power source 513 may heat the heating member 511 to heat the lower plate 420b. The heating power source 513 may be a direct current power source. The filter 515 may block the RF voltage (power) applied by the power unit 600 described later from being delivered to the heating power source 513.

The cooling fluid supply unit 521 may store a cooling fluid for cooling the upper plate 520a. The cooling fluid supply unit 521 may supply a cooling fluid to the cooling flow path 421 via the fluid supply channel 523. The cooling fluid supplied to the cooling flow path 421 may flow along the cooling flow path 421 to lower the temperature of the upper plate 420a. Additionally, the fluid valve 525 may be installed in the fluid supply channel 523 to control whether the cooing fluid supply unit supplies a cooling fluid, or the amount of cooling fluid supplied per unit time. The fluid valve 525 may be an on/off valve, or may be a flow regulating valve.

The power source RF may apply a Radio Frequency (RF) voltage to the lower electrode 240. The power source RF may apply an RF voltage to the lower electrode 240 to form an electric field in the interior space 101.

The ring unit 700 may be disposed at an edge region of the support unit 200. The ring unit 700 may include an edge ring 710, an insulating body 720, and a coupling ring 730.

The edge ring 710 may be disposed below the edge region of the substrate W. At least a portion of the edge ring 710 may be configured to be disposed below the edge region of the substrate W. The edge ring 710 may have an overall ring shape. The edge ring 710 may be configured such that, when viewed from the top, a portion overlaps the edge region of the substrate W and another portion surrounds the outer periphery of the substrate W. A top surface of the edge ring 710 may include an inner top surface, an outer top surface, and an inclined top surface. The inner top surface may be a top surface adjacent to the center region of the substrate W. The outer top surface may be a top surface that is farther from the center region of the substrate W than the inner top surface. The inclined top surface may be a top surface provided between the inner top surface and the outer top surface. The inclined top surface may be a top surface upwardly inclined in a direction away from the center of the substrate W. The edge ring 710 may extend the electric field formation region such that the substrate W is positioned at the center of the region where the plasma is formed. The edge ring 710 may be a focus ring. The edge ring 710 may be provided from a material including Si, or SiC.

The insulating body 720 may be configured to surround the edge ring 710 when viewed from the top. The insulating body 720 may be provided of an insulating material. The insulating body 720 may be provided to include an insulating material, such as quartz, or ceramic.

The coupling ring 730 may be disposed below the edge ring 710 and the insulating body 720. The coupling ring 730 may be surrounded by the edge ring 710, the insulating body 720, the lower electrode 240, and the dielectric plate 210. The coupling ring 710 may include a ring body 731 and a ring electrode E (an example of a conductive component). The ring body 731 may be provided from an insulating material. For example, the ring body 731 may be provided with an insulating material, such as quartz, or ceramic. The ring body 731 may be configured to enclose the ring electrode E. The ring electrode E may be provided from a conductive material, such as a material including metal.

The utility box UB may provide a port to which the cable IC may be connected. The cable IC may be electrically connected to the outer wall of the chamber 100 via the utility box UB. One end of the cable IC may be connected to the outer wall of the chamber 100 via the utility box UB, and the other end may be connected to the edge impedance controller EC. Further, the cable IC may be provided with the resonance control circuit TC.

When the power source RF) applies an RF voltage to the lower electrode 240, plasma may be generated in the interior space 101. An RF electric field may be formed in the interior space 101 by the RF voltage applied by the power source RF. The RF signal configuring the RF electric field may be coupled to the ring electrode E. The RF signal coupled to the ring electrode E may also be coupled to the cable IC that is connected to the chamber 100 via the utility box IC. This is because the chamber 100 is formed of a conductive material.

The edge impedance controller EC may include circuit elements, such as resistors, capacitors, and inductors, as described later. The circuit elements, such as resistors, capacitors, and inductors, of the edge impedance controller EC may be provided as variable elements, or may be provided as fixed elements. Depending on the circuit elements of the edge impedance controller EC, the impedance of the edge impedance controller EC may vary.

When the impedance of the edge impedance controller EC is small, the RF signal flow to the cable IC is large. As the RF signal flow to the cable IC increases, the plasma density in the edge region of the substrate W decreases.

When the impedance of the edge impedance controller EC is large, the RF signal flow to the cable IC is small. As the RF signal flow to the cable IC decreases, the plasma density in the edge region of the substrate W increases.

In other words, as the impedance of the edge impedance controller EC is varied, the plasma density in the edge region of the substrate W may be varied. The user may change the impedance of the edge impedance controller EC by adjusting the size of the resistance of the circuit elements, the capacitance of the capacitor, the inductance of the inductor, and the like, and thereby adjust the plasma density in the edge region of the substrate W.

Further, the cable IC may be provided with the resonance control circuit TC. The resonance control circuit TC may be a circuit including a capacitor, an inductor, and a sensor, as described later. The capacitors may be provided in plurality. The capacitors may be variable capacitors. The plurality of capacitors may be connected in parallel. The paralleled capacitors may be connected in series with an inductor. A sensor may be installed at the rear end of the inductor. The sensor may be a current sensor that may measure the current flowing in the cable IC. Alternatively, the sensor may be a voltage sensor capable of measuring the voltage applied to the resonance control circuit TC. Optionally, the sensor may be a sensor including both a voltmeter and an ammeter to measure both voltage and current.

The resonance control circuit TC may control the resonance point of the process module 50. The process module 50 may each have a unique resonance point, depending on the impedance across the process module 50 from the power source RF. As the process module 50 is operated many times, the configurations of the process module 50 may be deformed due to degradation, etching, and the like. In this case, the impedance across the process module 50 from the power source RF may change. As the impedance across the process module 50 from the power source RF changes, the resonance point of the process module 50 may also change.

The resonance control circuit TC may adjust the impedance across the process module 50 from the power source RF. In other words, the resonance control circuit TC may control the resonance point (resonant frequency) of the process module 50 by adjusting the impedance across the process module 50 from the power source RF.

The configurations of the process modules 50 described in FIG. 2 may be equally applicable to the first process module 50A, the second process module 50B, the third process module 50C, and the fourth process module 50D.

For example, the first process module 50A may include a first chamber 100A, a first power source RFA, a first ring electrode EA, a first utility box UBA, a first lower electrode 240A, a first cable ICA, a first resonance control circuit TCA, and a first edge impedance controller ECA.

The second process module 50B may include a second chamber 100B, a second power source RFB, a second ring electrode EB, a second utility box UBB, a second lower electrode 240B, a second cable ICB, a second resonance control circuit TCB, and a second edge impedance controller ECB.

The third process module 50C may include a third chamber 100C, a third power source RFC, a third ring electrode EC, a third utility box UBC, a third lower electrode 240C, a third cable ICC, a third resonance control circuit TCC, and a third edge impedance controller ECC.

The fourth process module 50D may include a fourth chamber 100D, a fourth power source RFD, a fourth ring electrode ED, a fourth utility box UBD, a fourth lower electrode 240D, a fourth cable ICD, a fourth resonance control circuit TCD, and a fourth edge impedance controller ECD.

The first to fourth chambers 100A to 100D, the first to fourth power sources RFA to RFD, the first to fourth ring electrodes EA to ED, the first to fourth utility boxes UBA to UBD, the first to fourth lower electrodes 240A to 240D, the first to fourth cables ICA to ICD, and the first to fourth resonance control circuits TCA to TCD, the first to fourth edge impedance controllers ECA to ECD may have substantially the same structure and function as the chamber 100, the power source RF, the ring electrode E, the utility box UB, the lower electrode 240, the cable IC, the resonance control circuit TC, and the edge impedance controller EC described above.

Further, the first to fourth resonance control circuits TCA to TCD may each include first variable capacitors C1A and C2A, second variable capacitors C1B and C2B, third variable capacitors C1C and C2C, and fourth variable capacitors CID and C2D connected in parallel.

Further, the first to fourth resonance control circuits TCA to TCD may include a first inductor LA, a second inductor LB, a third inductor LC, and a fourth inductor LD connected in series with the variable capacitors, respectively.

Further, the first to fourth resonance control circuits TCA to TCD may include a first sensor SA, a second sensor SB, a third sensor SC, and a fourth sensor SD connected in series with the inductors, respectively.

Further, the first to fourth edge impedance controllers ECA to ECD may include inductors LPA, LPB, LPC, and LPD, resistors RPA, RPB, RPC, and RPD, and capacitors CPA, CPB, CPC, and CPD, respectively.

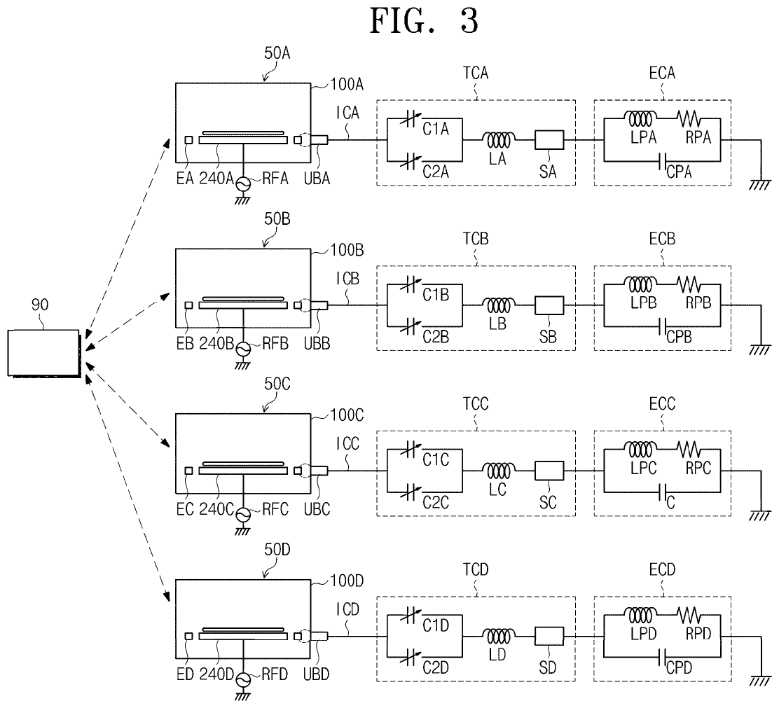

FIG. 3 is a diagram for illustrating a matching method of process modules according to an exemplary embodiment of the present invention.

Referring now to FIG. 3, the substrate processing apparatus 1 according to the exemplary embodiment of the present invention includes the plurality of process modules 50. The plurality of process modules 50 each have the chamber 100, the power source RF, the ring electrode E, the utility box UB, the lower electrode 240, the cable IC, the resonance control circuit TC, and the edge impedance controller EC.

In this case, the impedance across the chamber 100 from the power source RF is the same between the process modules 50. This is because when the process modules 50 are each set to the same process recipe, the impedance across the chamber 100 from the power source RF should be the same between the process modules 50, so that the processing rate for the substrate W processed in each of the process modules 50 is the same. However, even when the configurations of the process modules 50 are manufactured with the same specifications, the impedance across the chamber 100 from the power source RF may vary slightly between the process modules 50 due to manufacturing tolerances of the configurations, matching errors between the configurations, and the like.

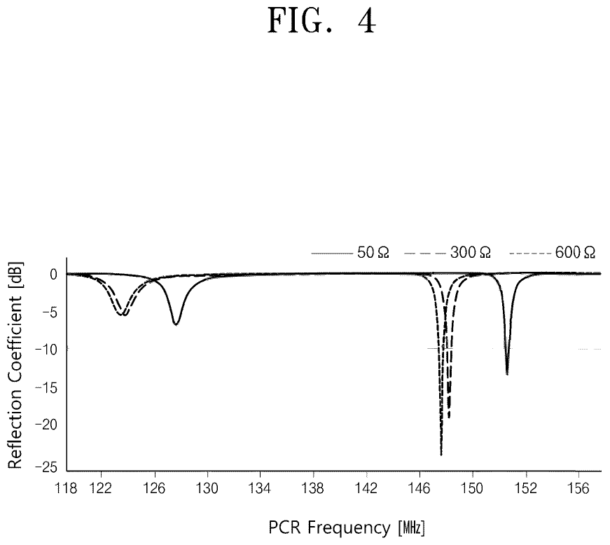

FIG. 4 is a graph for illustrating the variation of a resonance point when the cable connecting the edge impedance controller and the chamber changes.

FIG. 4 shows experimental data for the frequency at which the reflection coefficient is lowest when the cable IC provided between the edge impedance controller EC and the chamber 100 is changed, and more specifically, when the length of the cable IC is varied. Referring to FIG. 4, it may be seen that when the length of the cable IC is varied (i.e., the impedance of the cable IC is varied), the resonant frequency changes.

As the length of the cable IC varies, the impedance of the cable IC itself varies. By varying the lengths of the cable ICs installed between the edge impedance controller EC and the chamber 100, the magnitude of the impedance across the chamber 100 from the power source RF may also change, and the resonance point of the process module 50 may also change.

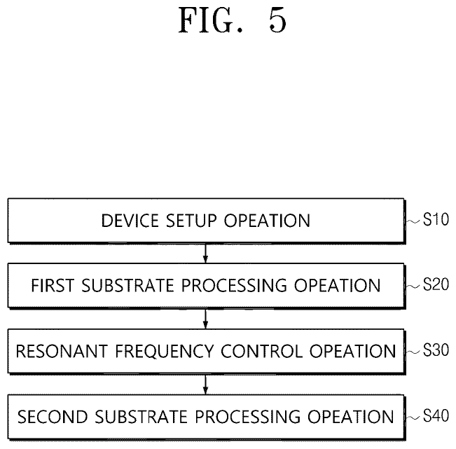

FIG. 5 is a flow chart for illustrating a substrate processing method according to an exemplary embodiment of the present invention.

Referring to FIGS. 3 and 5, a substrate processing method, which is a method of manufacturing a semiconductor device according to an exemplary embodiment of the present invention, may include a device setup operation S10, a first substrate processing operation S20, a resonant frequency control operation S30, and a second substrate processing operation S40.

The device setup operation S10 may include matching resonance points of the process modules 50 to each other. Matching the resonance points of the process modules 50 to each other may mean matching the impedance across the chamber 100 from the RF power source of each process module 50. The device setup operation S10 may essentially involve changing the length of the cable IC to match any slight resonance point differences that may occur between the process modules 50.

For example, the resonance points between the first process module 50A and the second process module 50B may be matched by installing the first cable ICA having a first length in the first process module 50A and installing the second cable ICB having a second length different from the first length in the second process module 50B.

In some cases, the device setup operation S10 may include, in addition to changing the length of the cable IC, the resonance points between the process modules 50 may be matched by replacing the elements in the resonance control circuit TC of the process modules 50, or controlling the variable elements in the resonance control circuit TC.

For example, the resonance points between the first process module 50A and the second process module 50B may be matched to each other by replacing the first inductor LA of the first resonance control circuit TCA with a first inductor LA including a different inductance, or adjusting the capacitance of the first variable capacitors C1A and C2A, and replacing the second inductor LB of the second resonance control circuit TCB with a second inductor LB having a different inductance, or adjusting the capacitance of the second variable capacitors C1B and C2B.

Whether the resonance points between the process modules 50 are matched with each other may be determined by applying a voltage from the power source RF to the lower electrode 240 and measuring the magnitude of the current flowing through the sensors SA, SB, SC, and SD of the resonance control circuit TC.

When the device setup operation S10 ends, the first substrate processing operation S20 is performed. In the first substrate processing operation S20, each of the process modules 50 performs a processing process on the substrate W. The first substrate processing operation S20 may be performed until each process module 50 processes a set number of substrates W. Alternatively, the first substrate processing operation S20 may be performed for a set period of time after the first substrate processing operation S20 is started.

After the first substrate processing operation S20 is performed, the process modules 50 may be deformed. For example, the inner walls of the chamber 100 may be etched, or deformation may occur due to degradation of the cables ICs. Deformation of the process modules 50 may cause the process modules 50 to have different resonance points.

Therefore, after processing the set number of substrates W in the first substrate processing operation S20, or after a set period of time has elapsed since the first substrate processing operation S20 started, the resonant frequency control operation S30 is performed.

The resonant frequency control operation S30 may be performed by generating, by the controller 90, a control signal to control the variable elements of the resonance control circuit TC. Unlike the device setup operation S10, the resonant frequency control operation S30 may be performed automatically by the control signal generated by the controller 90 without the involvement of an operator.

In the resonant frequency control operation S30, the impedance of the variable element may be changed by a value preset in the controller 90. For example, the resonant frequency control operation S30 may include changing the capacitance value of the variable capacitor of the resonance control circuit TC by a value preset in the controller 90.

In contrast, in the resonant frequency control operation S30, the power source RF applies a voltage to the lower electrode 240, a sensor in the resonance control circuit TC measures a current, and the impedance of the variable element of the resonance control circuit TC may be varied until the current measured by the sensor is equal to the magnitude of the current measured in the device setup operation S10.

In other words, in the resonant frequency control operation S30, the resonance point of the process module 50 that was changed while performing the first substrate processing operation S20 may be changed back to initial resonance points, which is the resonance point at the time of the device setup operation S10. The change of the resonance point may be performed for each of the process modules 50, so that the resonance points between the process modules 50 are equally matched.

When the resonant frequency control operation S30 is complete, the second substrate processing operation S40 may be performed in which the process modules 50 once again process the substrate W.

The substrate processing operations S20 and S40 and the resonant frequency control operation S30 may be performed alternately and repeatedly.

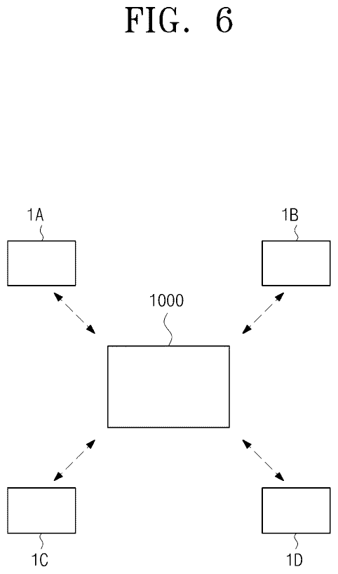

In the example described above, the present invention has been described based on the case where TTTM is performed between the process modules 50 of a single substrate processing device 1 as an example, but is not limited to. For example, as illustrated in FIG. 6, a semiconductor manufacturing line may be equipped with substrate processing apparatuses 1A, 1B, 1C, and 1D of the same type as the substrate processing apparatus 1. An integrated controller 1000 controlling these substrate processing apparatuses 1A, 1B, 1C, and 1D may apply the resonant frequency control operation S30 described above in the same/similar manner to the substrate processing apparatuses 1A, 1B, 1C, and 1D.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

1. A manufacturing method, comprising:
a device setup operation of matching resonance points of a first process module and a second process module different from the first process module with each other;
a first substrate processing operation of processing a substrate in the first process module and/or the second process module; and
a resonant frequency control operation of adjusting the resonance points of the first process module and the second process module that change while performing the first substrate processing operation to initial resonance points,
wherein the resonant frequency control operation includes controlling at least one of a variable element of a first resonance control circuit of the first process module and a variable element of a second resonance control circuit of the second process module to adjust the resonance points of the first process module and the second process module to the initial resonance points.

2. The manufacturing method of claim 1, wherein the first process module includes: a first chamber; a first power source that is an RF power source for generating plasma or regulating a flow of plasma in the first chamber; a first cable coupled to an RF signal applied by the first power source; and a first impedance controller coupled to the first cable, and
the second process module includes: a second chamber; a second power source that is an RF power source for generating plasma or regulating a flow of plasma in the second chamber; a second cable coupled to an RF signal applied by the second power source; and a second impedance controller connected with the second cable.

3. The manufacturing method of claim 2, wherein the device setup operation includes adjusting a length of at least one of the first cable and the second cable.

4. The manufacturing method of claim 2, wherein the device setup operation includes controlling at least one of variable elements of the first resonance control circuit and the second resonance control circuit to match the resonance points of the first process module and the second process module with each other.

5. The manufacturing method of claim 1, further comprising:
a second substrate processing operation, performed after the resonant frequency control operation, in which the first process module and/or the second process module processes the substrate.

6. The manufacturing method of claim 1, wherein the resonant frequency control operation is performed when a set number or more of substrates have been processed in the first substrate processing operation.

7. The manufacturing method of claim 1, wherein the resonant frequency control operation is performed when a set period of time has elapsed since the first substrate processing operation has been performed.

8. A process module matching method of matching resonance points of a plurality of process modules,
wherein the plurality of process modules each includes a chamber, a controller, and a cable connecting the controller and the chamber, and
the resonance points of the plurality of process modules are matched by differentiating lengths of the cables of the plurality of process modules.

9. The process module matching method of claim 8, wherein each of the cables is provided with a resonance control circuit including at least one variable element, and
the plurality of process modules regulates the variable elements of the resonance control circuits after processing a set number of substrates.

10. The process module matching method of claim 9, wherein the resonance points of the process modules are matched by adjusting the variable elements.

11. The process module matching method of claim 10, wherein the resonance points of the process modules are matched to the initial resonance points by adjusting the variable elements.

12.-20. (canceled)
